(19) United States
(12) Patent Application Publication
(10) Pub. No.: US 2020/0273999 A1
(43) Pub. Date: Aug. 27, 2020

(54) LOW-TEMPERATURE POLYSILICON (LTPS) THIN FILM TRANSISTOR (TFT) AND THE MANUFACTURING METHOD THEREOF

(71) Applicant: Wuhan China Star Optoelectronics Semiconductor Display Technology Co., Ltd., Wuhan, Hubei (CN)

(72) Inventor: Guoxia YI, Wuhan, Hubei (CN)

(21) Appl. No.: 15/776,347

(22) PCT Filed: Mar. 12, 2018
(86) PCT No.: PCT/CN2018/078660

§ 371 Date: May 15, 2018

(30) Foreign Application Priority Data
Jan. 30, 2018 (CN) 201810090423.5

(51) Int. Cl. H01L 29/786; H01L 29/66; H01L 29/10

(52) U.S. Cl. CPC H01L 29/78675; H01L 29/1037; H01L 29/66757

(57) ABSTRACT

The present disclosure relates to a low-temperature polysilicon (LTPS) thin film transistor (TFT). The LTPS TFT includes a ring-shaped polysilicon layer on a substrate, a first insulation layer on the substrate and the polysilicon layer, a gate on the first insulation layer, a second insulation layer on the first insulation layer and the gate, and a source and a drain on the second insulation layer. The source and the drain respectively passing through the second insulation layer and the first insulation layer to contact with the polysilicon layer. By forming the ring-shaped polysilicon layer, the width of the trench of the TFT can be reduced so as to facilitate the heat dissipation of the transistor. Thus, the stability of the transistor may be enhanced to realize the display panel having high resolution and low power consumption.

### BACKGROUND OF THE INVENTION

### 1. Field of the Invention

The present disclosure relates to TFT technology, and more particularly to a LTPS TFT and the manufacturing method thereof.

### 2. Discussion of the Related Art

At present, a-Si TFTs have been widely adopted as switching elements of display panels, but the attributes, such as thin, lightweight, high-precision, high-brightness, high reliability, and low power consumption of the a-Si TFT are still limited to some extent. Compared to a-Si TFTs, LTPS TFTs are characterized by a polysilicon layer of high electron mobility, and thus the above requirements may be easily realized.

However, while being characterized by the high electron mobility, the heat generation may be increased accordingly, which may impact the reliability of the products.

### SUMMARY

To achieve the above-mentioned purpose, the LTPS TFT and the manufacturing method thereof are proposed to reduce the heat generation by reducing a width of the trench.

In one aspect, a LTPS TFT includes: a ring-shaped polysilicon layer on a substrate; a first insulation layer on the substrate and the polysilicon layer; a gate on the first insulation layer; a second insulation layer on the first insulation layer and the gate; and
a source and a drain on the second insulation layer, the source and the drain respectively passing through the second insulation layer and the first insulation layer to contact with the polysilicon layer.

Wherein a longitudinal cross-section of the polysilicon layer includes two axisymmetric triangular shapes, each of the triangular shapes includes a first straight side, a second straight side, and an arc side, the first straight side is arranged on the substrate, a first end of the second straight side connects with a first end of the first straight side, the arc side connects between the second end of the first straight side and the second end of the second straight side, the arc side is concave toward an internal space defined by the first straight side, the second straight side, and the arc side.

Wherein a cross-section of the polysilicon layer is ring-shaped.

Wherein a dimension of the cross-section within an inner cavity of the polysilicon layer gradually decreases along a direction facing away from the substrate.

Wherein the LTPS TFT further includes a buffer layer between the substrate and the polysilicon layer.

In another aspect, a manufacturing method of LTPS TFT includes: forming a ring-shaped polysilicon layer on a substrate; forming a first insulation layer on the substrate and the polysilicon layer; forming a gate on the first insulation layer; forming a second insulation layer on the first insulation layer and the gate; and forming a source and a drain on the second insulation layer, the source and the drain respectively passing through the second insulation layer and the first insulation layer to contact with the polysilicon layer.

Wherein the step of forming the ring-shaped polysilicon layer on the substrate further includes: forming a flat layer on the substrate, a longitudinal cross-section of the flat layer is an inferior arc, and a cross-section of the flat layer is circular; forming an amorphous silicon layer on the substrate and the flat layer, the amorphous silicon layer includes a first portion on the substrate and a second portion on the flat layer; forming a ring-shaped photoresist layer at a junction of the first portion and the second portion; etching the amorphous silicon layer to form the ring-shaped amorphous silicon layer and removing the photoresist layer; etching the flat layer so as to remove the flat layer; and applying a solid phase crystallization process to the ring-shaped amorphous silicon layer to form the ring-shaped polysilicon layer.

Wherein a slope angle of the flat layer is in a range from 60 to 70 degrees.

Wherein a thickness of the flat layer is in a range from 2.5 μm to 3 μm.

Wherein, before the step of forming the ring-shaped polysilicon layer, the method further includes: forming a buffer layer on the substrate.

In view of the above, by forming the ring-shaped polysilicon layer, the width of the trench of the TFT can be reduced so as to facilitate the heat dissipation of the transistor. Thus, the stability of the transistor may be enhanced to realize the display panel having high resolution and low power consumption.

### BRIEF DESCRIPTION OF THE DRAWINGS

The features and advantages of embodiments of the claimed invention will be more apparent in view of the following description taken in conjunction with the accompanying drawings.

FIG. 1 is a schematic view of the LTPS TFT in accordance with one embodiment of the present disclosure.

FIG. 2 is a schematic view showing the projection of the polysilicon layer on the buffer layer in accordance with one embodiment of the present disclosure.

FIG. 3 is a cross-sectional view of the polysilicon layer in accordance with one embodiment of the present disclosure.

FIGS. 4A-4F are schematic view showing the steps relating to the manufacturing process of the LTPS TFT in accordance with one embodiment of the present disclosure.

FIGS. 5A-5F are schematic view showing the steps relating to the manufacturing process of the polysilicon layer in accordance with one embodiment of the present disclosure.

FIG. 6 is a schematic view of a slope angle of a flat layer in accordance with one embodiment of the present disclosure.

### DETAILED DESCRIPTION OF THE EMBODIMENTS

Embodiments of the invention will now be described more fully hereinafter with reference to the accompanying drawings, in which embodiments of the invention are shown.

Various example embodiments will now be described more fully with reference to the accompanying drawings in which some example embodiments are shown. In the drawings, the thicknesses of layers and regions may be exaggerated for clarity. In the following description, in order to avoid the known structure and/or function unnecessary detailed description of the concept of the invention result in confusion, well-known structures may be omitted and/or functions described in unnecessary detail.

In the drawings, the thickness of layers and regions are exaggerated for clarity. The same reference numerals denote the same components throughout the specification and the drawings.

It will be understood that when an element such as a layer, film, region, or substrate is referred to as being “in” or “formed on” another element. The element can be directly or directly formed on another element, or intermediate elements may also be configured. Alternatively, when an element is referred to as being “directly on” or “directly formed on” another element, it can be understand that no intermediate elements have been configured.

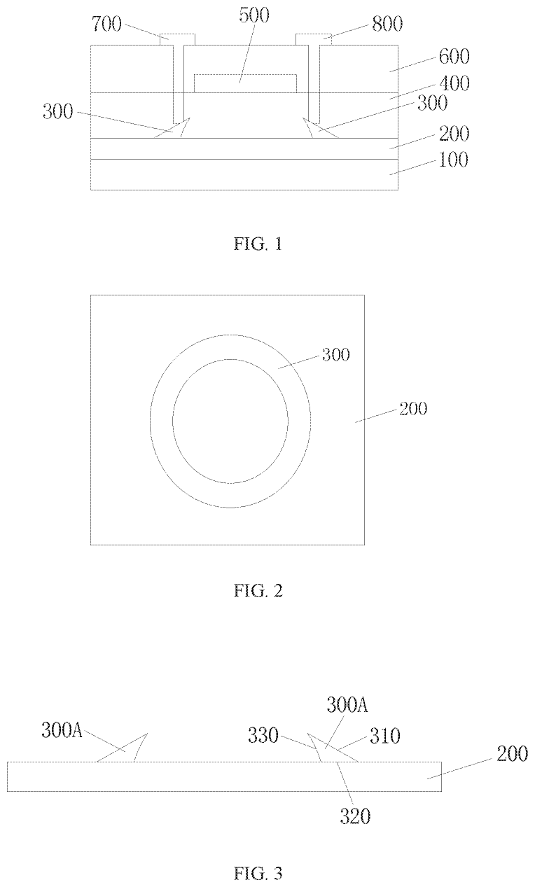

FIG. 1 is a schematic view of the LTPS TFT in accordance with one embodiment of the present disclosure.

Referring to FIG. 1, the LTPS TFT in the present disclosure includes a substrate 100, a buffer layer 200, a polysilicon layer 300, a first insulation layer 400, a gate 500, a second insulation layer 600, a source 700, and a drain 800.

The substrate 100 may be a glass substrate. The buffer layer 200 is arranged on the substrate 100. In one embodiment, the buffer layer 200 may be, but not limited to, formed by stacking the SiNₓ and SiOₓ. The buffer layer 200 is configured to prevent the metallic ions within the substrate 100 from being diffused to the polysilicon layer 300, which may avoid the defect center formation and current leakage. In another example, the buffer layer 200 may be excluded.

The polysilicon layer 300 is formed on the buffer layer 200. The polysilicon layer 300 may be, but not limited to, ring-shaped.

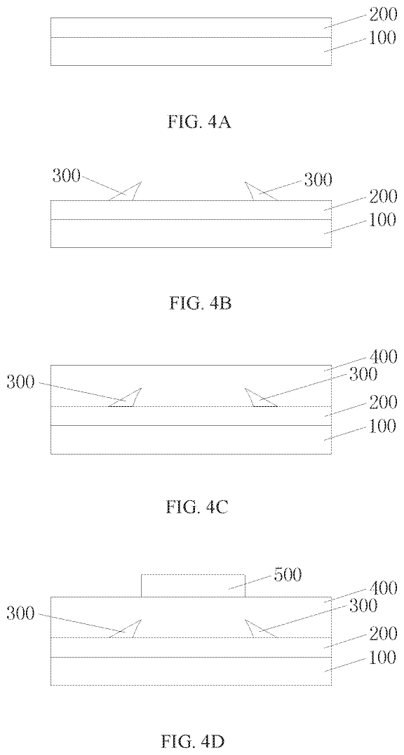

The cross-section of the polysilicon layer 300 is also ring-shaped. The cross-section of the polysilicon layer 300 refers to the cross-section of the polysilicon layer 300 parallel to the surface of the buffer layer 200 carrying the polysilicon layer 300. That is, the projection of the polysilicon layer 300 on the buffer layer 200 is ring-shaped (see FIG. 2).

FIG. 2 is a schematic view showing the projection of the polysilicon layer on the buffer layer in accordance with one embodiment of the present disclosure.

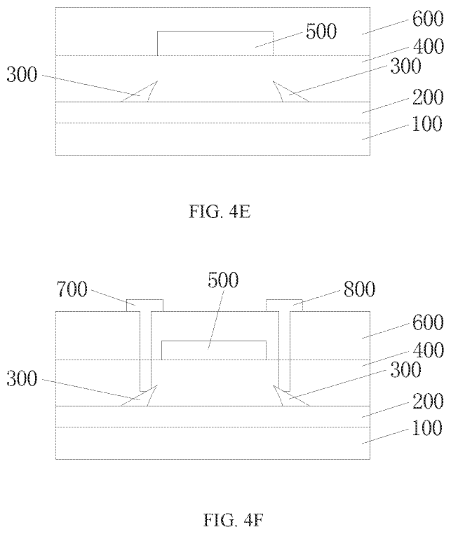

The longitudinal cross-section of the polysilicon layer 300 includes two axisymmetric triangular, as shown in FIG. 1. Here, the longitudinal cross section of the polysilicon layer 300 refers to a cross-section of the polysilicon layer 300 that is perpendicular to the surface of the buffer layer 200 carrying the polysilicon layer 300. In addition, the longitudinal cross-section of the polysilicon layer 300 is shown independently in FIG. 3 for illustration. FIG. 3 is a cross-sectional view of the polysilicon layer in accordance with one embodiment of the present disclosure.

Referring to FIGS. 1 and 3, the longitudinal cross-section of the polysilicon layer 300 includes two axisymmetric triangular shapes 300A. Each of the triangular shapes 300A includes a first straight side 310, a second straight side 320, and an arc side 330. The first straight side 310 is arranged on the buffer layer 200, a first end of the second straight side 320 connects with a first end of the first straight side 310, a second end of the second straight side 320 faces away a second end of the first straight side 310. That is, the second straight side 320 and the first straight side 310 cooperatively define a predetermined angle, i.e., an acute angle. The arc side 330 connects between the second end of the first straight side 310 and the second end of the second straight side 320. In addition, the arc side 330 is concave toward an internal space defined by the first straight side 310, the second straight side 320, and the arc side 330.

In one example, the curvature of each point on the arc side 330 is the same, that is, the arc side 330 is an arc.

Further, a dimension of the cross-section within an inner cavity of the polysilicon layer 300 gradually decreases along a direction facing away from the buffer layer 200. Here, the inner cavity of the polysilicon layer 300 is formed to extend circumferentially by arc side 330 of two axially symmetrical triangular shapes 300A.

With such configuration of the polysilicon layer 300, the width of the trench of the TFT may be reduced.

The first insulation layer 400 is arranged on the buffer layer 200 and the polysilicon layer 300. In addition, the first insulation layer 400 is configured to protect the polysilicon layer 300. The first insulation layer 400 may be a single layer of SiNₓ or SiOₓ or a stacked structure of SiNₓ/SiOₓ.

The gate 500 is arranged on the first insulation layer 400. The gate 500 may be MoAlMo or TiAlTi.

The second insulation layer 600 is arranged on the first insulation layer 400 and the gate 500. The second insulation layer 600 is also configured to protect the gate 500. The second insulation layer 600 may be a single layer of SiNₓ or SiOₓ or a stacked structure of SiNₓ/SiOₓ.

The source 700 and the drain 800 are arranged on the second insulation layer 600, and are spaced apart from one another. The source 700 and the drain 800 may be MoAlMo or TiAlTi. The source 700 and the drain 800 respectively passes through the second insulation layer 600 and the first insulation layer 400 so as to respectively contact with the polysilicon layer 300. The source 700 and the drain 800 respectively contacts with the second straight side 320 of the two triangular shapes 300A. Thus, the dimension of the contacted region is small, which contributes to the reduction of the trench width of the TFTs.

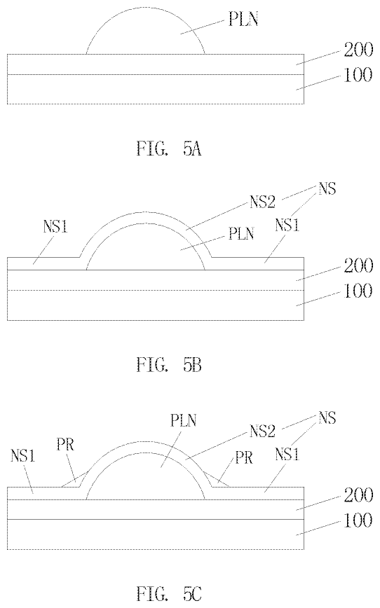

The manufacturing method of the LTPS TFT will be described hereinafter. FIGS. 4A-4F are schematic view showing the steps relating to the manufacturing process of the LTPS TFT in accordance with one embodiment of the present disclosure.

Step 1: referring to FIG. 4A, the buffer layer 200 is formed on the substrate 100. It can be understood that step 1 may be skipped when the buffer layer 200 is excluded from the configuration.

Step 2: referring to FIG. 4B, the ring-shaped polysilicon layer 300 is formed on the buffer layer 200.

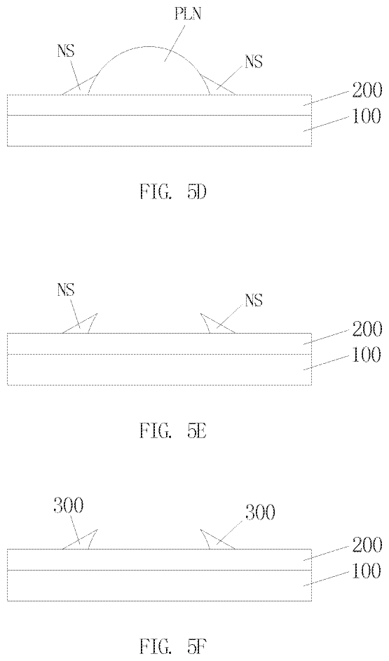

FIGS. 5A-5F are schematic view showing the steps relating to the manufacturing process of the polysilicon layer in accordance with one embodiment of the present disclosure.

Referring to FIG. 5A, a flat layer (PLN) is formed on the buffer layer 200. The longitudinal cross-section of the flat layer (PLN) is an inferior arc, and the cross-section of the flat layer (PLN) is circular. Here, the longitudinal section of the flat layer (PLN) refers to a cross-section of the flat layer (PLN) that is parallel to the surface of the buffer layer 200 carrying the flat layer (PLN). The longitudinal section of the flat layer (PLN) refers to a section that faces the flat layer (PLN) perpendicular to the surface of the buffer layer 200 carrying the flat layer (PLN). Here, the flat layer (PLN) having a predetermined pattern may be formed by applying exposure, development, etching, or the like process to a flat material layer.

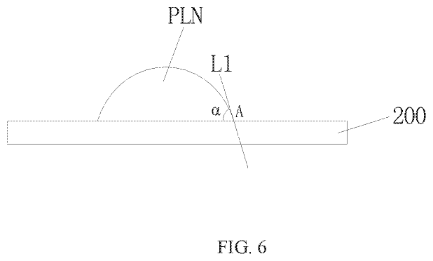

Further, the thickness of the flat layer (PLN) may be in, but not limited to, a range from 2.5 μm to 31 μm. In addition, the slope angle of the flat layer (PLN) may be in, but not limited to, a range from 60 to 70 degrees. FIG. 6 is a schematic view of a slope angle of a flat layer in accordance with one embodiment of the present disclosure.

Referring to FIG. 6, the contact point of the circular arc of the flat layer (PLN) and the buffer layer 200 is set to point A, and the arc tangent line L1 of the flat layer (PLN) is made at point A. The acute angle (α) between the arc tangent line L1 and the surface of the buffer layer 200 carrying the flat layer (PLN) is the slope angle.

Referring to FIG. 5B, an amorphous silicon layer NS is formed on the buffer layer 200 and the flat layer (PLN). The amorphous silicon layer includes a first portion NS1 located on the buffer layer 200 and a second portion NS2 located on the flat layer (PLN).

Referring to FIG. 5C, a ring-shaped photoresist layer PR is formed at the junction of the first portion NS1 and the second portion NS2. Here, the photoresist layer PR having a predetermined pattern may be formed by applying the exposure, development, etching, or the like process to the photoresist material layer. The shape of the photoresist layer PR is substantially the same as the shape of the polysilicon layer 300 described above, that is, the cross-section of the photoresist layer PR is also ring-shape. In addition, the longitudinal cross-section of the photoresist layer PR also includes two axisymmetric triangles.

Referring to FIG. 5D, the amorphous silicon layer NS is etched to form a ring-shaped amorphous silicon layer (NS), and the photoresist layer PR is removed. Here, the ring-shaped amorphous silicon layer (NS) also has the same shape as that of the ring-shaped polysilicon layer 300 described above, that is, the cross-section of the ring-shaped amorphous silicon layer (NS) is ring-shaped. And the longitudinal cross-section of the ring-shaped amorphous silicon layer (NS) also includes two axisymmetric triangular.

Referring to FIG. 5E, the flat layer (PLN) is etched and removed.

Referring to FIG. 5F, the ring-shaped amorphous silicon layer (NS) is crystallized by a solid phase crystallization method to form the ring-shaped polysilicon layer 300.

In step 3: referring to FIG. 4C, the first insulation layer 400 is formed on the buffer layer 200 and the polysilicon layer 300.

In step 4: referring to FIG. 4D, the gate 500 is formed on the first insulation layer 400.

In step 5: referring to FIG. 4E, the second insulation layer 600 is formed on the first insulation layer 400 and the gate 500.

In step 6: referring to FIG. 4F, the source 700 and the drain 800 are formed on the second insulation layer 600. The source 700 and the drain 800 respectively passes through the second insulation layer 600 and the first insulation layer 400 so as to respectively contact with the polysilicon layer 300.

In view of the above, by forming a polysilicon layer having a ring-shaped shape, the width of the trench of the TFT can be reduced so as to facilitate the heat dissipation of the transistor. Thus, the stability of the transistor may be enhanced to realize the display panel having high resolution and low power consumption.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A low-temperature polysilicon (LTPS) thin film transistor (TFT), comprising:
a ring-shaped polysilicon layer on a substrate;
a first insulation layer on the substrate and the polysilicon layer;
a gate on the first insulation layer;
a second insulation layer on the first insulation layer and the gate; and
a source and a drain on the second insulation layer, the source and the drain respectively passing through the second insulation layer and the first insulation layer to contact with the polysilicon layer.

2. The LTPS TFT as claimed in claim 1, wherein a longitudinal cross-section of the polysilicon layer comprises two axisymmetric triangular shapes, each of the triangular shapes comprises a first straight side, a second straight side, and an arc side, the first straight side is arranged on the substrate, a first end of the second straight side connects with a first end of the first straight side, the arc side connects between the second end of the first straight side and the second end of the second straight side, the arc side is concave toward an internal space defined by the first straight side, the second straight side, and the arc side.

3. The LTPS TFT as claimed in claim 1, wherein a cross-section of the polysilicon layer is ring-shaped.

4. The LTPS TFT as claimed in claim 2, wherein a cross-section of the polysilicon layer is ring-shaped.

5. The LTPS TFT as claimed in claim 3, wherein a dimension of the cross-section within an inner cavity of the polysilicon layer gradually decreases along a direction facing away from the substrate.

6. The LTPS TFT as claimed in claim 4, wherein a dimension of the cross-section within an inner cavity of the polysilicon layer gradually decreases along a direction facing away from the substrate.

7. The LTPS TFT as claimed in claim 1, wherein the LTPS TFT further comprises a buffer layer between the substrate and the polysilicon layer.

8. A manufacturing method of low-temperature polysilicon (LTPS) thin film transistors (TFTs), comprising:
forming a ring-shaped polysilicon layer on a substrate;
forming a first insulation layer on the substrate and the polysilicon layer;
forming a gate on the first insulation layer;
forming a second insulation layer on the first insulation layer and the gate; and
forming a source and a drain on the second insulation layer, the source and the drain respectively passing through the second insulation layer and the first insulation layer to contact with the polysilicon layer.

9. The manufacturing method of the LTPS TFTs as claimed in claim 8, wherein the step of forming the ring-shaped polysilicon layer on the substrate further comprises:
forming a flat layer on the substrate, a longitudinal cross-section of the flat layer is an inferior arc, and a cross-section of the flat layer is circular;
forming an amorphous silicon layer on the substrate and the flat layer, the amorphous silicon layer comprises a first portion on the substrate and a second portion on the flat layer;
forming a ring-shaped photoresist layer at a junction of the first portion and the second portion;
etching the amorphous silicon layer to form the ring-shaped amorphous silicon layer and removing the photoresist layer;
etching the flat layer so as to remove the flat layer;
applying a solid phase crystallization process to the ring-shaped amorphous silicon layer to form the ring-shaped polysilicon layer.

10. The manufacturing method of the LTPS TFTs as claimed in claim 9, wherein a slope angle of the flat layer is in a range from 60 to 70 degrees.

11. The manufacturing method of the LTPS TFTs as claimed in claim 9, wherein a thickness of the flat layer is in a range from 2.5 μm to 3 μm.

12. The manufacturing method of the LTPS TFTs as claimed in claim 10, wherein a thickness of the flat layer is in a range from 2.5 μm to 3 μm.

13. The manufacturing method of the LTPS TFTs as claimed in claim 8, wherein, before the step of forming the ring-shaped polysilicon layer, the method further comprises:
forming a buffer layer on the substrate.
